(19) United States
(12) Patent Application Publication
(10) Pub. No.: US 2026/0180343 A1
(43) Pub. Date: Jun. 25, 2026

(54) SMART SELF-CHARGING A WEARABLE ELECTRONIC DEVICE

(71) Applicant: INTERNATIONAL BUSINESS MACHINES CORPORATION, ARMONK, NY (US)

(72) Inventor: Vivek Mahalingam, BENGALURU (IN)

(21) Appl. No.: 18/991,802

(22) Filed: Dec. 23, 2024

(51) Int. Cl. H02J 7/00; G06F 1/16; H02J 7/35; H02J 50/00; H10N 10/10; H10N 30/30

(52) U.S. Cl. CPC H02J 7/42; G06F 1/163; H02J 7/35; H02J 50/001; H10N 10/10; H10N 30/302; H02J 2105/44

(57) ABSTRACT

A method, computer program product, and computer system for charging a wearable device that a user wears. A command to charge, during a specified sequence of time periods, a battery is received. The battery powers the wearable device and is disposed in the wearable device. The wearable device includes at least two chargers for charging the battery and a sensor associated with each charger are selected from: (i) a solar charger and an associated photoconductive sensor for sensing light intensity, (ii) a thermal charger and an associated temperature gradient sensor for sensing a temperature difference, between the user's body temperature and an ambient temperature, and (iii) a piezo charger and an associated motion sensor for sensing the users motion. The user's motion is the user's linear acceleration and/or angular velocity. For each time period, a preferred charger is selected and subsequently triggered to charge the battery.

### BACKGROUND

The present invention relates generally to charging an electronic device, and more specifically to smart self-charging a wearable electronic device.

### SUMMARY

Embodiments of the present invention provide a wearable device and both a method and a computer program product for charging the wearable device that a user wears.

One or more processors in the wearable device, receive a command to charge, to at least a specified charge during a specified sequence of N time periods denoted as time periods 1, . . . , N subject to N being at least 1, a battery that powers the wearable device and is disposed in the wearable device.

The wearable device includes at least two chargers for charging the battery and a sensor associated with each charger.

The at least two chargers and associated sensors are selected from the group consisting of (i) a solar charger and an associated photoconductive sensor for sensing a parameter of light intensity that energizes the solar charger, (ii) a thermal charger and an associated temperature gradient sensor for sensing a parameter of a temperature difference, between the user's body temperature and an ambient temperature, that energizes the thermal charger, and (iii) a piezo charger and an associated motion sensor for sensing a parameter of the users motion that energizes the piezo charger, wherein the user's motion is the user's linear acceleration, the user's angular velocity, or a combination thereof

For each time period n (n=1, . . . , N): at the beginning of time period n, the one or more processors (i) select a preferred charger of the at least two chargers for charging the battery throughout time period n; and (ii) trigger the preferred charger to charge the battery throughout time period n.

### BRIEF DESCRIPTION OF THE DRAWINGS

FIG. 1 depicts components in a wearable device that a user wears and is powered by a battery, in accordance with embodiments of the present invention.

FIG. 2 is a flow chart describing a method for charging the wearable device that the user wears, in accordance with embodiments of the present invention.

FIG. 3 is a flow chart of a process for selecting a preferred charger of at least two chargers for charging the battery throughout the time period n of N time periods (n=1, . . . , N), in accordance with embodiments of the present invention.

FIG. 4 is a flow chart of a process for generating and storing in a data store 60: sensor parameter data, predicted parameter data, and predicted charging rates, in accordance with embodiments of the present invention.

FIG. 5 depicts a process in which a neural network comprising at least two transformers respectively used for predicting at least two parameters that respectively energize at least two chargers, in accordance with embodiments of the present invention.

FIG. 6 depicts a process in which the transformer of the neural network in FIG. 5 is trained to predict parameters that energize the at least two chargers, in accordance with embodiments of the present invention.

FIG. 7 is a flow chart describing training the transformer of the neural network, in accordance with embodiments of the present invention.

FIG. 8 illustrates a computer system, in accordance with embodiments of the present invention.

FIG. 9 depicts a computing environment which contains an example of an environment for the execution of at least some of the computer code involved in performing the inventive methods, in accordance with embodiments of the present invention.

### DETAILED DESCRIPTION

Embodiments of the present invention provide a mechanism for efficiently self-charging a battery within an electronic wearable device that a user wears, wherein the battery energizes the electronic wearable device.

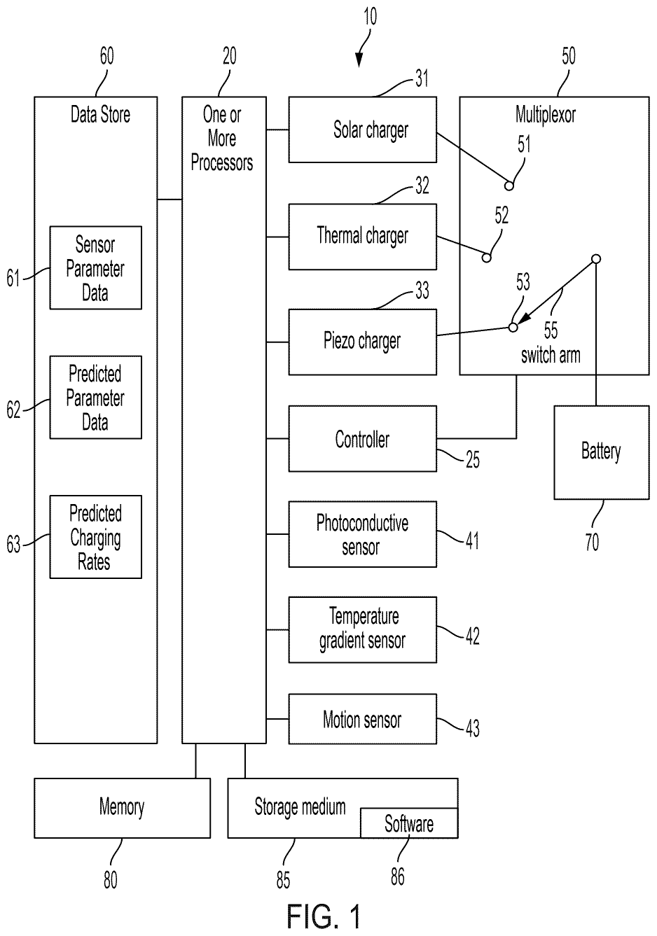

FIG. 1 depicts components in a wearable device 10 that a user wears and is powered by a battery 70, in accordance with embodiments of the present invention. The wearable device 10 is a wearable electronic device.

The wearable device 10 may be, inter alia, an earphone, a smartwatch watch, smart glasses, a smart bracelet, smart headgear, etc.

The wearable device 10 comprises one or more processors 20, memory 80 which represents one or more memories, a data store 60, a computer-readable storage medium 85, a controller 25, a battery 70, chargers (a solar charger 31, a thermal charger 32, a piezo charger 33), a multiplexer 50, and sensors (a photoconductive sensor 41, a temperature gradient sensor 42, a motion sensor 43).

The chargers (a solar charger 31, a thermal charger 32, a piezo charger 33) are each configured to individually charge the battery 70 via a multiplexer 50 that functions as a three-way switch via a movable switch arm 55 configured to be moved to a connection point 51, 52 or 53 to electrically connect the solar charger 31, the thermal charger 32 or the piezo charger 33, respectively, to the battery 70.

Embodiments of the present invention provide a method for selecting, at each time period of a sequence of time periods, a preferred charger for charging the battery 70 during each time period.

In one embodiment, the preferred charger is selected from the solar charger 31, the thermal charger 32, and the piezo charger 33.

In one embodiment, only two chargers of the preceding three chargers (the solar charger 31, the thermal charger 32, the piezo charger 33) are present in the wearable device 10, and the preferred charger is selected from the two chargers which may be: (the solar charger 31 and the thermal charger 32), (the solar charger 31 and the piezo charger 33), or (the thermal charger 32 and the piezo charger 33).

In one embodiment, the one or more processors 20 control the functioning of the multiplexer 50 via a controller 25.

In one embodiment for which controller 25 does not exist in the wearable device 10 and the one or more processors 20 directly control the functioning of the multiplexer 50.

A photo conductive sensor 41 senses a parameter of light intensity that energizes the solar charger 31.

A temperature gradient sensor 42 senses a parameter of temperature difference, between the user's body temperature and an ambient temperature surrounding the user's body, that energizes the thermal charger 32.

A motion sensor 43 senses a parameter of the user's motion that energizes the piezo charger 33. The user's motion is the user's linear acceleration, the user's angular velocity, or a combination of the user's linear acceleration and the user's angular velocity.

The data store 60 includes sensor parameter data 61, predicted parameter data 62, and predicted charging rates 63.

The sensor parameter data 61 includes parameters of: light intensities sensed by the photoconductive sensor 41 at historical times (i.e., previous times) and a current time, temperature differences sensed by the temperature gradient sensor 42 at the historical times and the current time, and the user's motion sensed by motion sensor 43 at the historical times and the current time.

Embodiments of the present invention use the sensor parameter data 61 at the previous times and the current time to: (i) generate and update a neural network having a transformer architecture to predict the predicted parameter data 62, and (ii) select a preferred charger at a current time to charge the battery 70 during a current time period or during both a current time period and future time periods.

The sensor parameter data 61 are the parameters sensed by all of the sensors, respectively, within the wearable device 10 at predefined or specified times and are stored within the data store 60. There is a historical time window within which the sensor parameter data 61 is used to predict the predicted parameter data 62. In one embodiment, the historic time window has a fixed time span which advances in time as time advances, so that the sensor parameter data 61 that is earlier in time than the current historical time window is periodically deleted from the data store 60.

The predicted parameter data 62 includes predicted parameters (at a current time and future times) of: light intensity, temperature difference (between the user's body temperature and an ambient temperature surrounding the user's body), and the user's motion (the user's linear acceleration and/or the user's angular velocity).

The predicted parameter data 62 is used to select a preferred charger at the current time and future times. When some predicted parameters of the predicted parameter data 62 are no longer needed, such predicted parameters may be periodically deleted from the predicted parameter data 62. Thus, in one embodiment, some of the predicted parameter data 62 for historical times are periodically deleted from the data store 60.

The predicted parameters in the predicted parameter data 62 are inferred from the sensor parameter data 61. In one embodiment, the predicted parameters are predicted from the sensor parameter data 61 via use of a neural network that includes multiple transformers as described infra in conjunction with FIGS. 5-7.

The predicted charging rates 63 include predicted charging rates (for the current time and future times) of: the solar charger 31, the thermal charge of 32, and the piezo charger 33.

The predicted charging rates 63 are used to select a preferred charger at the current time and future times and are no longer needed, and are thus periodically deleted, for times that were previously current and future times but have currently passed and are now historical times. Thus, the predicted charging rates 63 for historical times are periodically deleted from the data store 60.

The predicted charging rates 63 are inferred from the predicted parameters. Thus, the charging rate of the solar charger 31 at a given time is predicted from the light intensity at the given time, the charging rate of the solar thermal 32 at the given time is predicted from the temperature differences at the given time, and the charging rate of the piezo charger 33 at the given time is predicted from the user's motion at the given time.

In one embodiment, the charging rate of the solar charger 31 may be determined from a formula or table obtained from the manufacturer of the solar charger 31, expressing the charging rate of the solar charger 31 as a function of light intensity.

In one embodiment, the charging rate of the solar charger 31 may be determined from a formula or table obtained experimentally from measurements of the charging rate of the solar charger 31 and the associated light intensity at different values of light intensity.

In one embodiment, the charging rate of the solar charger 31 may be calculated from kyI, wherein I is light intensity and ky is a constant obtained from the manufacturer of the solar charger 31 or obtained experimentally. However, the preceding linear dependence of the charging rate of the solar charger 31 on light intensity may not be valid at very low levels of light intensity (i.e., at light intensity so low that the solar panel cannot generate enough voltage to satisfy the battery's charging requirements so that the battery cannot be charged effectively).

In one embodiment, the charging rate of the thermal charger 32 may be obtained from a formula or table, obtained from the manufacturer of the thermal charger 32, expressing the charging rate of the thermal charger 32 as a function of temperature difference (between the user's body temperature and an ambient temperature surrounding the user's body).

In one embodiment, the charging rate of the thermal charger 32 may be obtained from a formula or table, obtained experimentally from measurements of the charging rate of the thermal charger 32 and the associated temperature difference at different values of temperature difference.

In one embodiment, the charging rate of the thermal charger 32 is k_{T}(ΔT)², wherein ΔT is temperature difference and k_{T} is a constant obtained from the manufacturer of the thermal charger 32 or obtained experimentally.

The preceding proportionality of the charging rate of the thermal charger 32 to (ΔT)² is based on the following analysis. The thermal charger 32 generates a voltage V, based on the Seebeck effect, by converting the temperature difference ΔT into the voltage via V=α ΔT where the Seebeck coefficient α that depends on material properties of the thermal charger 32. The charging rate of the thermal charger 32 is proportional to the electrical power P generated by the thermal charger 32 where P is proportional to V² (i.e., to (α ΔT)²). Thus, the charging rate of the thermal charger 32 is proportional to (ΔT)².

In one embodiment, the charging rate of the piezo charger 33 may be obtained from a formula or table, obtained from the manufacturer of the piezo charger 33, expressing the charging rate of the piezo charger 33 as a function of the user's motion.

In one embodiment, the charging rate of the piezo charger 33 may be obtained from a formula or table, obtained experimentally from measurements of the charging rate of the piezo charger 33 and the user's motion (i.e., at different values of: the user's linear acceleration, the user's angular velocity, or a combination of the user's linear acceleration and the user's angular velocity)

In one embodiment, the computer readable medium 85 (which may include one or more computer readable hardware storage devices) includes a computer program product comprising the software 86 (which may be program code, executable instructions, etc.), wherein the software 86 is executable by the one or more processors 20 via the memory 80 (which may comprise one or more memories that may include random access memory (RAM)) to perform any of the methods and processes provided by embodiments of the present invention.

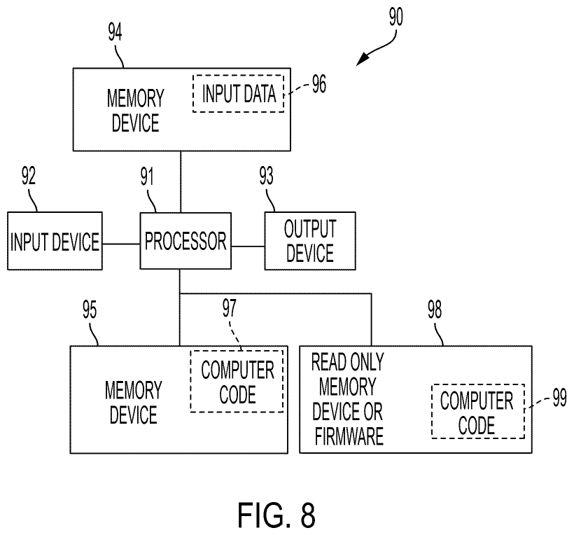

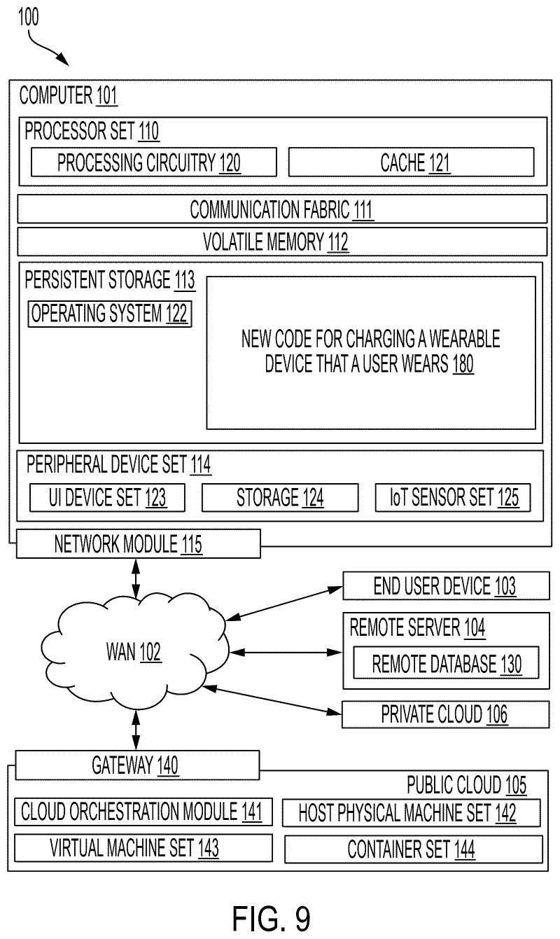

The wearable device 10 may include any of the features and characteristics of the computer system 90 and the computing environment 100 described infra in conjunction with FIG. 8 and FIG. 9, respectively.

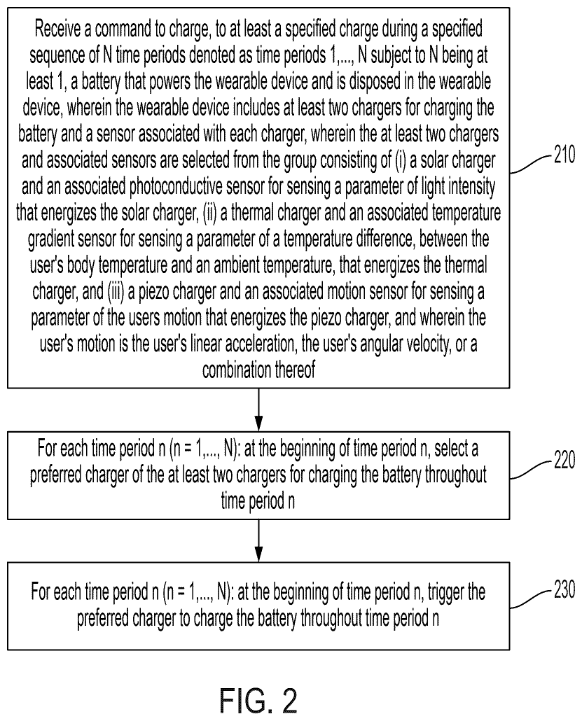

FIG. 2 is a flow chart describing a method for charging the wearable device 10 that the user wears, in accordance with embodiments of the present invention. The flow chart of FIG. 2 includes steps 210-230.

Step 210 receives a command to charge, to at least a specified charge during a specified sequence of N time periods denoted as time periods 1, . . . , N subject N being at least 1, a battery 70 that powers the wearable device 10 and is disposed in the wearable device 10.

The wearable device 10 includes at least two chargers for charging the battery 70 and a sensor associated with each charger, wherein the at least two chargers and associated sensors are selected from the group consisting of (i) a solar charger 31 and an associated photoconductive sensor 41 for sensing a parameter of light intensity that energizes the solar charger 31, (ii) a thermal charger 32 and an associated temperature gradient sensor 42 for sensing a parameter of a temperature difference, between the user's body temperature and an ambient temperature, that energizes the thermal charger 32, and (ii) a piezo charger 33 and an associated motion sensor 43 for sensing a parameter of the users motion that energizes the piezo charger 33, wherein the user's motion is the user's linear acceleration, the user's angular velocity, or a combination thereof.

In one embodiment, the at least two chargers and associated sensors consist of three chargers and associated sensors (i.e., solar charger 31 and the photoconductive sensor 41, the thermal charger 32 and the temperature gradient sensor 42, and the piezo charger 33 and the motion sensor 43).

In one embodiment, the at least two chargers and associated sensors consist of two chargers and associated sensors.

In one embodiment, the two chargers and associated sensors consist of: the two chargers of the solar charger 31 and the thermal charger 32, and the associated sensors of the photoconductive sensor 41 and the temperature gradient sensor 42, respectively.

In one embodiment, the two chargers and associated sensors consist of: the two chargers of the solar charger 31 and the piezo charger 33, and the associated sensors of the photoconductive sensor 41 and the motion sensor 43, respectively.

In one embodiment, the two chargers and associated sensors consist of: the two chargers of the thermal charger 32 and the piezo charger 33, and the associated sensors of the temperature gradient sensor 42 and the motion sensor 43, respectively.

Steps 230 and 240 are each performed at the beginning of time period n (n=1, . . . , N).

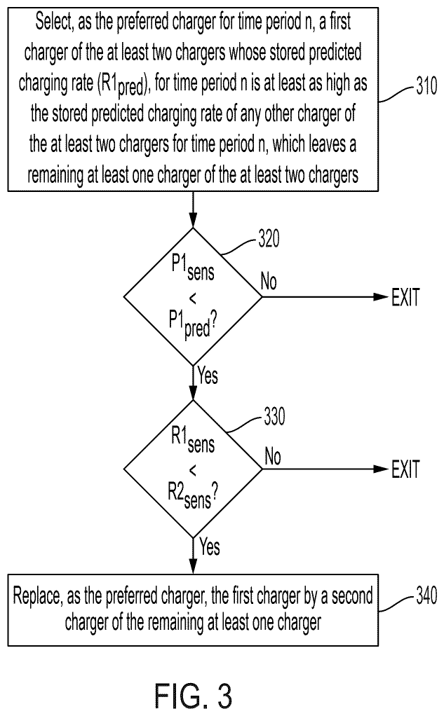

Step 220 selects a preferred charger of the at least two chargers for charging the battery 70 throughout time period n. Step 220 is described in more detail in FIG. 3.

Step 230 triggers the preferred charger to charge the battery 70 throughout time period n.

FIG. 3 is a flow chart of a process for selecting a preferred charger of at least two chargers for charging the battery 70 throughout time period n, in accordance with embodiments of the present invention. The flow chart of FIG. 3, which includes steps 310-340, describes step 220 of FIG. 2 in more detail.

The wearable device 10 comprises the data store 60 that stores: (i) in the sensor parameter data 61, sensed values of the parameters that energize each charger of the at least two chargers for each time period of S time periods such that the S time periods encompass the N time periods, wherein the sensed values were sensed by the at least two sensors respectively associated with the at least two chargers; (ii) in the predicted parameter data 62, predicted values 61 of the parameters that energize each charger of the at least two chargers for each time period of P time periods such that the P time periods encompass the N time periods, and (iii) in the predicted charging rates 63, predicted charging rates for each charger of the at least two chargers for each time period of the P time periods.

Step 310 selects, as the preferred charger for time period n, a first charger of the at least two chargers whose stored predicted charging rate (R1_{pred}) for time period n is at least as high as the stored predicted charging rate of any other charger of the at least two chargers for time period n, which leaves a remaining at least one charger of the at least two chargers.

Step 320 determines whether P1ₛₑₙₛ<P1_{pred}, wherein P1ₛₑₙₛ is the stored sensed value of the parameter associated with the first charger for time period n and P1_{pred} is the stored predicted value of the parameter associated with the first charger for time period n. If so (Yes branch from step 320) then step 330 is next executed, and if not (No branch from step 320) then the process exits.

Step 330 determines whether R1ₛₑₙₛ<R2ₛₑₙₛ, wherein R1ₛₑₙₛ is the stored sensed value of the parameter associated with the first charger for time period n and R2ₛₑₙₛ is the stored sensed value of the parameter associated with a second charger of the remaining at least one charger for time period n, and wherein the stored predicted charging rate (R2ₛₜₒᵣ) of the second charger for time period n is at least as high as the stored predicted charging rate of any other charger of the remaining at least remaining charger for time period n. If so (Yes branch from step 330) then step 340 is next executed, and if not (No branch from step 330) then the process exits.

Step 340 replaces, as the preferred charger, the first charger by the second charger.

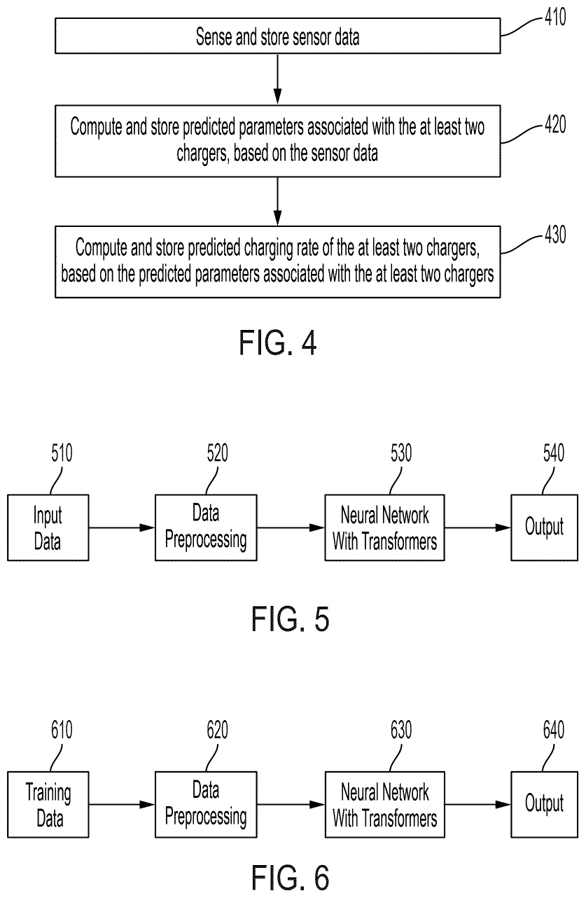

FIG. 4 is a flow chart of a process for generating and storing in the data store 60: the sensor parameter data 61, the predicted parameter data 62, and the predicted charging rates 63, in accordance with embodiments of the present invention. The flow chart of FIG. 4 includes steps 410-430.

Step 410 senses, by the photoconductive sensor 41, the temperature gradient sensor 42, and the motion sensor 43, light intensity, temperature difference, and motion, respectively, at discrete predetermined or specified times. Then, step 410 stores, in the data store 60, the sensed light intensity, the sensed temperature difference (between the user's body temperature and an ambient temperature surrounding the user's body), and the sensed motion (the user's linear acceleration and/or angular velocity) as the sensor parameter data 61 which becomes historical sensor data at future times.

Step 420 computes predicted parameters of light intensity, temperature difference (between the user's body temperature and an ambient temperature surrounding the user's body), and motion (the user's linear acceleration and/or angular velocity) for current and future times based on the sensor parameter data 61. Then, step 420 stores, in the data store 60 for the current and future times, the predicted light intensity, temperature difference (between the user's body temperature and an ambient temperature surrounding the user's body), and motion (the user's linear acceleration and/or angular velocity) as the predicted parameter data 62. FIGS. 5-7 describe step 420 in more detail.

Step 430 computes predicted charging rates of the at least two chargers selected from the solar charger 31, the thermal charger 32, and the piezo charger 33, at the same current and future times as for the predicted of light intensity, temperature difference, and motion, and based on the predicted of light intensity, temperature difference, and motion, respectively. Then, step 430 stores, in the data store 60 for the current and future times, the predicted charging rates of the at least two chargers as the predicted charging rates 63.

FIG. 5 depicts a process in which a neural network 530 comprising at least two transformers respectively used for predicting the at least two parameters that respectively energize the at least two chargers, in accordance with embodiments of the present invention.

The neural network 530 is stored within the software 86 in the storage medium 85.

Each transformer is specific to a respective parameter.

Each transformer includes a self-attention mechanism, an encoder, and a decoder.

The self-attention mechanism focuses on temporal dependencies which enable the transformer to key on important parts of a temporal input sequence by assigning higher weights to significant times on past dates that may strongly influence the parameter calculation on future dates.

The encoder processes historical data, allowing the transformer to capture temporal information from past dates and times, and embed associated time variables (year, month, day of month, week, day of week, time of day) into an embedding representation (e.g., one or more embedding vectors) that is used to provide the transformer with cyclic temporal relationships and patterns that are used for the parameter predictions. Each layer in the encoder refines the representation to provide additional information with respect to the temporal relationships and patterns that exist in the historical data. The transformer does not inherently understand a time order of the sensor data. Thus, the encoding includes positional encoding to give the transformer an understanding of time sequence ordering. Also, because the transformer does not inherently understand a time order of the sensor data, the sensor data can be processed in parallel to significantly reduce the computation time to predict the parameter and to train the transformer.

The decoder uses the embeddings generated by the encoder and the weight determined by the self-attention mechanism to generate predictions which corresponds to predicting current and future values of the parameters based on the encoded past parameters that were sensed. The decoder also uses the time-based inputs to provide context to account for time-based predictions of parameter values that vary with time. In one embodiment, the decoder uses predictions at previously predicted times as input for subsequent times, which allows the transformer to generate a full prediction time-based sequence of parameter values for current and future times.

In FIG. 5, input data 510 undergoes data preprocessing 520 from which the neural network 530 with at the least two transformers predict the at least two parameters that energize the at least two chargers, respectively, for present and future times. Each parameter (light intensity, temperature difference, user motion) is predicted from a different transformer specific to each parameter. Thus, there is a distinct transformer for the parameter of light intensity and is modelled on light intensity sensor data in the sensor parameter data 61 which is in the data store 60, a distinct transformer for the parameter of temperature difference (between the user's body temperature and an ambient temperature surrounding the user's body) and is modelled on temperature difference sensor data in the sensor parameter data 61 which is in in the data store 60, and a distinct transformer for the parameter of motion (the user's linear acceleration and/or angular velocity) and is modelled on motion sensor data in the sensor parameter data 61 which is in the data store 60. Each distinct transformer of the at least two transformers has been trained separately.

The output 540 includes the predicted parameters.

The predicted parameters are the at least two parameters selected from: light intensity, temperature difference (between the user's body temperature and an ambient temperature surrounding the user's body) and motion (the user's linear acceleration and/or angular velocity) associated with the at least two chargers selected from the solar charger 31, the thermal charger 32, and the piezo charger 33, respectively.

The input data 510 encompass current and future dates at which the parameters are to be predicted by the transformers respectively specific to the parameters.

The neural network 530 comprising the at least two transformers is modelled on time parameters selected from year, month, day of month, week, day of week, and time of day, for each date in the input data.

The data pre-processing 520 includes extracting the time parameters from the input data for each date and constructing embeddings (e.g., one or more embedding vectors) from the extracted time parameters.

FIG. 6 depicts a process in which the transformer of the neural network 530 in FIG. 5 is trained to predict parameters that energize the at least two chargers, in accordance with embodiments of the present invention.

In FIG. 6, training data 610 includes a training dataset selected from the sensor parameter data 61 in the data store 60. Time parameters selected from year, month, day of month, week, day of week, and time of day, and associated sensed parameter values, are extracted from the sensor parameter data 61.

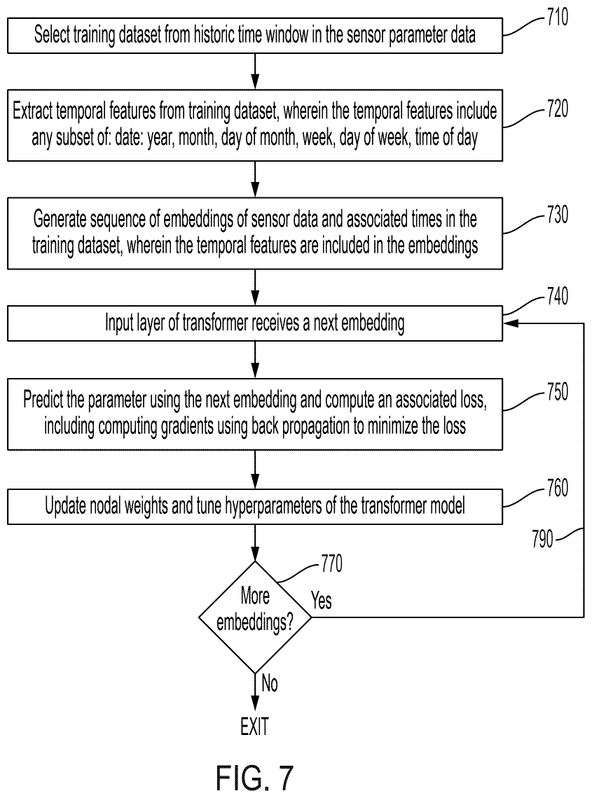

The training data 610 undergoes data preprocessing 620 from which the neural network with the at least one transformer 630 is trained to predict the parameters that energize the at least two chargers for present and future. The preprocessing 620 is described in more detail by steps 720 and 730 of FIG. 7

The output 640 may include, inter alia, any of: trained model weights and loss metrics.

After being trained, the neural network 530 in FIG. 5 becomes the neural network 630 in FIG. 6.

Details of the training process are presented in FIG. 7.

FIG. 7 is a flow chart describing training the transformer of the neural network 530 in FIG. 5, in accordance with embodiments of the present invention.

Since each transformer of the at least two transformers is specific to a different parameter of the at least two parameters respectfully associated with the at least two chargers, the flow chart of FIG. 7 is for any transformer of the at least two transformers. Each transformer has an architecture characterized by an input layer, hidden layers that include nodes and associated nodal parameters, and an output layer, as well as a self-attention mechanism, an encoder, and a decoder.

The training data for training each transformer includes the sensor parameter data 61.

The training data for training the transformer to predict current and future light intensities are the sensed light intensities in a historic time window of the light intensities in the sensor parameter data 61.

The training data for training the transformer to predict current and future temperature differences (between the user's body temperature and an ambient temperature surrounding the user's body) are the sensed temperature differences in a historic time window of the temperature differences in the sensor parameter data 61.

The training data for training the transformer to predict current and future user motions (the user's linear acceleration and/or angular velocity) are the sensed user motions in a historic time window of the user motions in the sensor parameter data 61.

The flow chart of FIG. 7 includes steps 710-770.

Step 710 selects a training dataset from the historic time window in the sensor parameter data 61. The historic time window defines a range of times within which the sensor parameter data 61 exists. In one embodiment, the training dataset encompasses the entire historic time window. In one embodiment, the training dataset encompasses only a subset of the historic time window that is smaller than the entire historic time window, wherein the subset may be a most recent subset of the entire historic time window or any other subset of the entire historic time window.

In one embodiment, the historic time window is divided into the training dataset and a validation data set, wherein the validation dataset is used to validate the trained transformer generated from the training dataset. In one embodiment, the training dataset encompasses 70-90% of the historic time window and the validation dataset encompasses 10-30% of the historic time window.

Steps 720 and 730 provide a more detailed description of step 620 of FIG. 6

Step 720 extracts temporal features from training dataset, wherein the temporal features may include any subset of: year, month, day of month, week, day of week, time of day. For example, the extracted temporal features may encompass: year, month, day of month, and time of day.

Step 730 generates a sequence of embeddings of the sensor data and associated times in the training dataset, wherein the extracted temporal features are included in the embeddings. Each embedding may encompass one or more historical times in the training dataset and may be expressed as one or more embedding vectors.

Steps 740-770 define each iteration of an iterative loop 790 performed by the transformer. Each iteration receives and processes a next embedding in the sequence of embeddings generated in step 730. For the first iteration, the next embedding is the first embedding in the sequence of embeddings.

In step 740, a next embedding of the sequence of embeddings is received by the input layer of the transformer. Steps 760 and 770 process the next embedding.

Step 750 predicts the parameter using the next embedding and computes an associated loss, including computing gradients using back propagation to minimize the loss. The loss is a measure of the difference between the parameter predicted in step 760 and the respective sensed parameter that is stored in the sensor parameter data 61. In one embodiment, the loss is a cost function that may be minimized via execution of a gradient descent algorithm

Step 760 updates the nodal weights and tunes hyper-parameters of the transformer. The hyper-parameters may include, inter alia learning rate, number of self-attention layers, etc.

Steps 760 and 770 utilize the self-attention mechanism, the encoder and the decoder.

The self-attention mechanism focuses on temporal dependencies which enable the transformer to key on important parts of a temporal input sequence by assigning higher weights to significant times on past dates that may strongly influence the parameter calculation on future dates.

The encoder enables the transformer to capture temporal information from past dates and times, and embed associated time variables (year, month, day of month, week, day of week, time of day) into an embedding representation that is used to provide the transform model with cyclic temporal relationships and patterns that are used for the parameter predictions. Each layer in the encoder provides additional information with respect to the temporal relationships and patterns that exist in the historical data.

The transformer does not inherently understand a time order of the sensor data. Thus, the encoding includes positional encoding to give the transformer an outstanding of time sequence ordering. The positional encoding enables the transformer to differentiate dates based on when the dates occurred in a time sequence. Also, because the transformer does not inherently understand a time order of the sensor data, the sensor data can be processed in parallel to significantly reduce the computation time to predict the parameter and to train the transformer.

The decoder uses the embeddings generated by the encoder and the weight determined by the self-attention mechanism to generate predictions which corresponds to predicting current and future values of the parameters, based on the encoded past parameters that were sensed. The decoder also uses the time-based inputs to provide context to account for time-based predictions of higher parameter values during peak hours or low parameter values during off hours. In addition, the decoder uses predictions at previously predicted times as input for subsequent times, which allows the transformer to generate a full prediction time-based sequence of parameter values for current and future times.

Step 770 determines whether there are one or more remaining embeddings that have not yet been received and processed by the transformer. If so (Yes branch from step 770) then the process exits, and if not (No branch from step 770) then the process loops back to step 740 to receive, and subsequently process in steps 750 and 760, the next embedding.

FIG. 8 illustrates a computer system 90, in accordance with embodiments of the present invention.

The computer system 90 includes a processor 91, an input device 92 coupled to the processor 91, an output device 93 coupled to the processor 91, and memory devices 94 and 95 each coupled to the processor 91. The processor 91 represents one or more processors and may denote a single processor or a plurality of processors. The input device 92 may be, inter alia, a keyboard, a mouse, a camera, a touchscreen, etc., or a combination thereof. The output device 93 may be, inter alia, a printer, a plotter, a computer screen, a magnetic tape, a removable hard disk, a floppy disk, etc., or a combination thereof. The memory devices 94 and 95 may each be, inter alia, a hard disk, a floppy disk, a magnetic tape, an optical storage such as a compact disc (CD) or a digital video disc (DVD), a dynamic random access memory (DRAM), a read-only memory (ROM), etc., or a combination thereof. The memory device 95 includes a computer code 97. The computer code 97 includes algorithms for executing embodiments of the present invention. The processor 91 executes the computer code 97. The memory device 94 includes input data 96. The input data 96 includes input required by the computer code 97. The output device 93 displays output from the computer code 97. Either or both memory devices 94 and 95 (or one or more additional memory devices such as read only memory device 96) may include algorithms and may be used as a computer usable medium (or a computer readable medium or a program storage device) having a computer readable program code embodied therein and/or having other data stored therein, wherein the computer readable program code includes the computer code 97. Generally, a computer program product (or, alternatively, an article of manufacture) of the computer system 90 may include the computer usable medium (or the program storage device).

In some embodiments, rather than being stored and accessed from a hard drive, optical disc or other writeable, rewriteable, or removable hardware memory device 95, stored computer program code 99 (e.g., including algorithms) may be stored on a static, nonremovable, read-only storage medium such as a Read-Only Memory (ROM) device 98, or may be accessed by processor 91 directly from such a static, nonremovable, read-only medium 98. Similarly, in some embodiments, stored computer program code 99 may be stored as computer-readable firmware, or may be accessed by processor 91 directly from such firmware, rather than from a more dynamic or removable hardware data-storage device 95, such as a hard drive or optical disc.

Still yet, any of the components of the present invention could be created, integrated, hosted, maintained, deployed, managed, serviced, etc. by a service supplier who offers to improve software technology associated with cross-referencing metrics associated with plug-in components, generating software code modules, and enabling operational functionality of target cloud components. Thus, the present invention discloses a process for deploying, creating, integrating, hosting, maintaining, and/or integrating computing infrastructure, including integrating computer-readable code into the computer system 90, wherein the code in combination with the computer system 90 is capable of performing a method for enabling a process for improving software technology associated with cross-referencing metrics associated with plug-in components, generating software code modules, and enabling operational functionality of target cloud components. In another embodiment, the invention provides a business method that performs the process steps of the invention on a subscription, advertising, and/or fee basis. That is, a service supplier, such as a Solution Integrator, could offer to enable a process for improving software technology associated with cross-referencing metrics associated with plug-in components, generating software code modules, and enabling operational functionality of target cloud components. In this case, the service supplier can create, maintain, support, etc. a computer infrastructure that performs the process steps of the invention for one or more customers. In return, the service supplier can receive payment from the customer(s) under a subscription and/or fee agreement and/or the service supplier can receive payment from the sale of advertising content to one or more third parties.

While FIG. 8 shows the computer system 90 as a particular configuration of hardware and software, any configuration of hardware and software, as would be known to a person of ordinary skill in the art, may be utilized for the purposes stated supra in conjunction with the particular computer system 90 of FIG. 8. For example, the memory devices 94 and 95 may be portions of a single memory device rather than separate memory devices.

A computer program product of the present invention comprises one or more computer readable hardware storage devices having computer readable program code stored therein, said program code containing instructions executable by one or more processors of a computer system to implement the methods of the present invention.

A computer system of the present invention comprises one or more processors, one or more memories, and one or more computer readable hardware storage devices, said one or more hardware storage devices containing program code executable by the one or more processors via the one or more memories to implement the methods of the present invention.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

FIG. 9 depicts a computing environment 100 which contains an example of an environment for the execution of at least some of the computer code involved in performing the inventive methods, in accordance with embodiments of the present invention. Such computer code includes new code for charging a wearable device that a user wears 180. In addition to block 180, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 180, as identified above), peripheral device set 114 (including user interface (UI) device set 123, storage 124, and Internet of Things (IOT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 180 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 180 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

CLOUD COMPUTING SERVICES AND/OR MICROSERVICES (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for charging a wearable device that a user wears, said method comprising:
receiving, by one or more processors in the wearable device, a command to charge, to at least a specified charge during a specified sequence of N time periods denoted as time periods 1, . . . , N subject to N being at least 1, a battery that powers the wearable device and is disposed in the wearable device, wherein the wearable device includes at least two chargers for charging the battery and a sensor associated with each charger, wherein the at least two chargers and associated sensors are selected from the group consisting of (i) a solar charger and an associated photoconductive sensor for sensing a parameter of light intensity that energizes the solar charger, (ii) a thermal charger and an associated temperature gradient sensor for sensing a parameter of a temperature difference, between the user's body temperature and an ambient temperature, that energizes the thermal charger, and (iii) a piezo charger and an associated motion sensor for sensing a parameter of the users motion that energizes the piezo charger, wherein the user's motion is the user's linear acceleration, the user's angular velocity, or a combination thereof;
for each time period n (n=1, . . . , N): (i) at the beginning of time period n, selecting, by the one or more processors, a preferred charger of the at least two chargers for charging the battery throughout time period n; and (ii) triggering, by the one or more processors, the preferred charger to charge the battery throughout time period n.

2. The method of claim 1,
wherein the wearable device comprises a data store that stores: (i) predicted values of the parameters that energize each charger of the at least two chargers for each time period of P time periods such that the P time periods encompass the N time periods, (ii) predicted charging rates for each charger of the at least two chargers for each time period of the P time periods, and (iii) sensed values of the parameters that energize each charger of the at least two chargers for each time period of S time periods such that the S time periods encompass the N time periods, wherein the sense values were sensed by the at least two sensors respectively associated with the at least two chargers;
wherein said selecting the preferred charger for time period n comprises: selecting, as the preferred charger for time period n, a first charger of the at least two chargers whose stored predicted charging rate (R1_{pred}) for time period n is at least as high as the stored predicted charging rate of any other charger of the at least two chargers for time period n, which leaves a remaining at least one charger of the at least two chargers.

3. The method of claim 2, wherein said selecting the preferred charger for time period n further comprises:
determining whether the stored sensed value (P1ₛₑₙₛ) of the parameter associated with the first charger for time period n is less than the stored predicted value (P1_{pred}) of the parameter associated with the one charger for time period n, and if so then if a charging condition is satisfied then replacing, as the preferred charger, the first charger by a second charger of the remaining at least one charger whose stored predicted charging rate (R2ₛₜₒᵣ) for time period n is at least as high as the stored predicted charging rate of any other charger of the remaining at least remaining charger for time period n, wherein the charging condition is that the stored sensed charging rate (R1ₛₑₙₛ) of the first charger for time period n is less than the sensed charging rate (R2ₛₑₙₛ) of the second charger for time period n.

4. The method of claim 3, wherein the charging condition is satisfied.

5. The method of claim 3, wherein the charging condition is not satisfied.

6. The method of claim 1, wherein the at least two chargers and associated sensors consist of three chargers and associated sensors.

7. The method of claim 1, wherein the at least two chargers and associated sensors consist of two chargers and associated sensors.

8. The method of claim 1, wherein the two chargers consist of the solar charger and the thermal charger.

9. The method of claim 1, wherein the two chargers consist of the solar charger and the piezo charger.

10. The method of claim 1, wherein the two chargers consist of the thermal charger and the piezo charger.

11. A computer program product in a wearable device, said computer program product comprising one or more computer readable hardware storage devices having computer readable program code stored therein, said program code containing instructions executable by one or more processors in the wearable device to implement a method for charging the wearable device that a user wears, said method comprising:
receiving, by the one or more processors, a command to charge, to at least a specified charge during a specified sequence of N time periods denoted as time periods 1, . . . , N subject to N being at least 1, a battery that powers the wearable device and is disposed in the wearable device, wherein the wearable device includes at least two chargers for charging the battery and a sensor associated with each charger, wherein the at least two chargers and associated sensors are selected from the group consisting of (i) a solar charger and an associated photoconductive sensor for sensing a parameter of light intensity that energizes the solar charger, (ii) a thermal charger and an associated temperature gradient sensor for sensing a parameter of a temperature difference, between the user's body temperature and an ambient temperature, that energizes the thermal charger, and (iii) a piezo charger and an associated motion sensor for sensing a parameter of the users motion that energizes the piezo charger, wherein the user's motion is the user's linear acceleration, the user's angular velocity, or a combination thereof;
for each time period n (n=1, . . . , N): (i) at the beginning of time period n, selecting, by the one or more processors, a preferred charger of the at least two chargers for charging the battery throughout time period n; and (ii) triggering, by the one or more processors, the preferred charger to charge the battery throughout time period n.

12. The computer program product of claim 11,
wherein the wearable device comprises a data store that stores: (i) predicted values of the parameters that energize each charger of the at least two chargers for each time period of P time periods such that the P time periods encompass the N time periods, (ii) predicted charging rates for each charger of the at least two chargers for each time period of the P time periods, and (iii) sensed values of the parameters that energize each charger of the at least two chargers for each time period of S time periods such that the S time periods encompass the N time periods, wherein the sense values were sensed by the at least two sensors respectively associated with the at least two chargers;
wherein said selecting the preferred charger for time period n comprises: selecting, as the preferred charger for time period n, a first charger of the at least two chargers whose stored predicted charging rate (R1_{pred}) for time period n is at least as high as the stored predicted charging rate of any other charger of the at least two chargers for time period n, which leaves a remaining at least one charger of the at least two chargers.

13. The computer program product of claim 12, wherein said selecting the preferred charger for time period n further comprises:
determining whether the stored sensed value (P1ₛₑₙₛ) of the parameter associated with the first charger for time period n is less than the stored predicted value (P1_{pred}) of the parameter associated with the one charger for time period n, and if so then if a charging condition is satisfied then replacing, as the preferred charger, the first charger by a second charger of the remaining at least one charger whose stored predicted charging rate (R2ₛₜₒᵣ) for time period n is at least as high as the stored predicted charging rate of any other charger of the remaining at least remaining charger for time period n, wherein the charging condition is that the stored sensed charging rate (R1ₛₑₙₛ) of the first charger for time period n is less than the sensed charging rate (R2ₛₑₙₛ) of the second charger for time period n.

14. The computer program product of claim 13, wherein the charging condition is satisfied.

15. The computer program product of claim 13, wherein the charging condition is not satisfied.

16. A wearable device, comprising one or more processors, one or more memories, and one or more computer readable hardware storage devices, said one or more hardware storage devices containing program code executable by the one or more processors via the one or more memories to implement a method for charging the wearable device that a user wears, said method comprising:
receiving, by the one or more processors, a command to charge, to at least a specified charge during a specified sequence of N time periods denoted as time periods 1, . . . , N subject to N being at least 1, a battery that powers the wearable device and is disposed in the wearable device, wherein the wearable device includes at least two chargers for charging the battery and a sensor associated with each charger, wherein the at least two chargers and associated sensors are selected from the group consisting of (i) a solar charger and an associated photoconductive sensor for sensing a parameter of light intensity that energizes the solar charger, (ii) a thermal charger and an associated temperature gradient sensor for sensing a parameter of a temperature difference, between the user's body temperature and an ambient temperature, that energizes the thermal charger, and (iii) a piezo charger and an associated motion sensor for sensing a parameter of the users motion that energizes the piezo charger, wherein the user's motion is the user's linear acceleration, the user's angular velocity, or a combination thereof;
for each time period n (n=1, . . . , N): (i) at the beginning of time period n, selecting, by the one or more processors, a preferred charger of the at least two chargers for charging the battery throughout time period n; and (ii) triggering, by the one or more processors, the preferred charger to charge the battery throughout time period n.

17. The wearable device of claim 16,
wherein the wearable device comprises a data store that stores: (i) predicted values of the parameters that energize each charger of the at least two chargers for each time period of P time periods such that the P time periods encompass the N time periods, (ii) predicted charging rates for each charger of the at least two chargers for each time period of the P time periods, and (iii) sensed values of the parameters that energize each charger of the at least two chargers for each time period of S time periods such that the S time periods encompass the N time periods, wherein the sense values were sensed by the at least two sensors respectively associated with the at least two chargers;
wherein said selecting the preferred charger for time period n comprises: selecting, as the preferred charger for time period n, a first charger of the at least two chargers whose stored predicted charging rate (R1_{pred}) for time period n is at least as high as the stored predicted charging rate of any other charger of the at least two chargers for time period n, which leaves a remaining at least one charger of the at least two chargers.

18. The wearable device of claim 17, wherein said selecting the preferred charger for time period n further comprises:
determining whether the stored sensed value (P1ₛₑₙₛ) of the parameter associated with the first charger for time period n is less than the stored predicted value (P1_{pred}) of the parameter associated with the one charger for time period n, and if so then if a charging condition is satisfied then replacing, as the preferred charger, the first charger by a second charger of the remaining at least one charger whose stored predicted charging rate (R2ₛₜₒᵣ) for time period n is at least as high as the stored predicted charging rate of any other charger of the remaining at least remaining charger for time period n, wherein the charging condition is that the stored sensed charging rate (R1ₛₑₙₛ) of the first charger for time period n is less than the sensed charging rate (R2ₛₑₙₛ) of the second charger for time period n.

19. The wearable device of claim 18, wherein the charging condition is satisfied.

20. The wearable device of claim 18, wherein the charging condition is not satisfied.
